(19) United States
(12) Patent Application Publication
(10) Pub. No.: US 2025/0297356 A1
(43) Pub. Date: Sep. 25, 2025

(54) METHOD AND APPARATUS FOR ION BEAM DIRECTIONAL DEPOSITION

(71) Applicant: Axcelis Technologies, Inc., Beverly, MA (US)

(72) Inventor: Glen Gilchrist, Wingdale, NY (US)

(21) Appl. No.: 19/086,293

(22) Filed: Mar. 21, 2025

Related U.S. Application Data
(60) Provisional application No. 63/569,018, filed on Mar. 22, 2024.
(60) Provisional application No. 63/569,029, filed on Mar. 22, 2024.
(60) Provisional application No. 63/631,518, filed on Apr. 9, 2024.

(51) Int. Cl. C23C 14/50; C23C 14/04; C23C 14/06; C23C 14/08; C23C 14/22; H01L 21/02

(52) U.S. Cl. CPC C23C 14/50; C23C 14/221; H01L 21/02115; H01L 21/02263; C23C 14/042; C23C 14/0605; C23C 14/0635; C23C 14/0652; C23C 14/081

(57) ABSTRACT

A deposition system has an ion deposition apparatus configured to direct a deposition species toward a workpiece along a path. The workpiece has one or more features having a gap defined by the one or more features. A workpiece support holds the workpiece to receive the deposition species at a predetermined tilt angle with respect to the path. The ion deposition apparatus deposits the deposition species on the one or more features, the workpiece support rotates the workpiece with respect to the path, growing a deposition film of the deposition species on the one or more features in a predetermined manner. The deposition film can seal the gap to define a sealed cavity. Alternatively, the one or more features can be a mask that is augmented by the deposition film to increase one or more dimensions of the mask.

### REFERENCE TO RELATED APPLICATIONS

This application claims the benefit of U.S. Provisional Application Ser. No. 63/569,018 filed Mar. 22, 2024, entitled, “MASK AUGMENTATION FOR NANOELECTRONICS FABRICATION”, U.S. Provisional Application Ser. No. 63/569,029 filed Mar. 22, 2024, entitled, “AIR GAP FOR ELECTRICAL ISOLATION IN CMOS AND OTHER INTEGRATED CIRCUITS”, and U.S. Provisional Application Ser. No. 63/631,518 filed Apr. 9, 2024, entitled, “METHOD AND APPARATUS FOR ION BEAM DIRECTIONAL DEPOSITION”, the contents of all of which are herein incorporated by reference in their entireties.

### TECHNICAL FIELD

The present invention relates generally to semiconductor processing, and more specifically to apparatuses, systems and methods for deposition of ions on a surface of a workpiece.

### BACKGROUND

During processing of a workpiece (e.g., a semiconductor wafer), various processes are typically performed to achieve various desired results for features formed on the workpiece. For example, in Complementary Metal-Oxide-Semiconductor (CMOS) processing, dielectric materials such as low-k dielectrics (e.g., solid dielectrics) are commonly formed for electrical isolation between gaps in CMOS features and similar integrated circuits. While low-k dielectrics offer lower capacitance compared to traditional dielectrics such as silicon dioxide (SiO₂), as device and feature sizes continue to decrease, low-k dielectrics can still exhibit deleterious capacitance. Low-k dielectric materials can also suffer from reliability issues such as moisture absorption or susceptibility to mechanical stress, either of which can affect device performance and longevity.

In other processes, such as in the fabrication of nano-electronic integrated devices (i.e., semiconductor devices), various mask layers are commonly formed on the workpiece. Degradation and/or reduction of a patterning mask layer (e.g., a device mask, a photoresist, or a hard mask) on the workpiece can occur during subsequent etching, ion implantation, or other semiconductor processing, thus resulting in a so-called deficient mask. The deficient mask, for example, can have a remaining mask layer that is too thin to proceed to the next fabrication step (e.g., an insufficient “mask budget”), or the remaining mask layer can be too thin to complete the current processing step without suffering process-induced damage on underlying metal or dielectric layers.

### SUMMARY

The present disclosure provides a novel method and system for transmitting ions and depositing atoms onto a surface of a workpiece in order to achieve various advantages over conventional semiconductor processing techniques. The following presents a simplified summary in order to provide a basic understanding of one or more aspects of the disclosure. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to the more detailed description that is presented later.

In accordance with one example, the present disclosure provides a deposition system comprising an ion deposition apparatus that is configured to direct a deposition species along a path. A workpiece support is configured to selectively support a workpiece along a support plane, wherein the workpiece comprises one or more features defining at least one gap. A positioning apparatus is further configured to selectively position the workpiece support with respect to the path to receive the deposition species, wherein the positioning apparatus is configured to selectively position the support plane of the workpiece support at a predetermined tilt angle with respect to the path, wherein the predetermined tilt angle is not orthogonal to the support plane. The workpiece support is further configured to selectively rotate the workpiece with respect to the path, wherein the ion deposition apparatus is configured to deposit the deposition species on a predetermined portion of the one or more features, thereby growing a deposition film comprised of the deposition species on the predetermined portion of the one or more features in a predetermined manner.

In one example, the deposition film can substantially seal the at least one gap to respectively define at least one gap isolation structure. In another example, the one or more features can comprise a mask, whereby the deposition film is configured to increase one or more dimensions of the mask. The mask, for example, can comprise one or more of a deficient mask, a device mask, a photoresist, and a hard mask.

The one or more features, for example, can comprise a plurality of vertical features defined on a surface of the workpiece, and wherein the at least one gap comprises at least one trench defined between at least two of the plurality of vertical features, and wherein the ion deposition apparatus is configured to deposit the deposition species proximate to a respective top opening of each of the at least one trench.

The workpiece support, for example, can be further configured to selectively vary the predetermined tilt angle with respect to the path between approximately 45° to 75°.

The ion deposition apparatus, for example, can comprise an ion implantation system configured to define an ion beam, wherein the ion beam comprises the deposition species. The deposition species, for example, can comprise one or more condensable species, wherein the ion deposition apparatus is configured to transmit the condensable species toward the workpiece in a gaseous phase, and wherein the condensable species is configured to condense on the workpiece. The deposition species, for example, can comprise one of Si⁺, SiH₃⁺, Si₂H₅⁺, Si₃H₇⁺, C⁺, CH₃⁺, C₇H₇⁺, Si, SiH₃, or metal atoms. In another example, the deposition species can comprise a high molecular weight molecule, such as one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄.

In accordance with another example, a method is provided for semiconductor processing, whereby a deposition beam is directed along a path, wherein the deposition beam comprises a deposition species. A workpiece is provided along the path, wherein the workpiece has one or more features defined thereon, and wherein the one or more features define one or more gaps extending between a lower portion and a top portion of the one or more features, respectively. In one example, the workpiece at a predetermined tilt angle with respect to the deposition beam, and the deposition species is deposited on the top portion of the one or more features. As such, a deposition film is defined on the top portion of the one or more features, whereby one or more dimensions of the top portion of the one or more features are increased. The predetermined tilt angle, the one or more features, and the deposition film, for example, generally prevent the deposition film from depositing on the lower portion of the one or more features. For example, the deposition film is generally prevented from depositing on the lower portion of the one or more features due to a shadowing effect.

In one example, the deposition beam comprises one of an ion beam and a neutral beam. The deposition beam, for example, can comprise a high molecular weight deposition species, such as one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄.

In another example, the method further comprises rotating the workpiece with respect to the deposition beam, wherein the deposition film is uniformly deposited on the top portion of the one or more features.

Depositing the deposition species on the top portion of the one or more features, for example, seals one of a gas or a vacuum within the one or more gaps.

Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a block diagram of an exemplary ion deposition system in accordance with several example aspects of the present disclosure.

FIG. 2 is a table illustrating energy per atom is equal associated with extraction voltage in accordance with one example of the present disclosure.

FIGS. 3A-3C are graphs illustrating various sputter yields at various extraction energies in accordance with various examples of the present disclosure.

FIGS. 4A-4D are cross-sectional views of a portion of a workpiece illustrating progressive stages of a deposition of a deposition species on a plurality of features on the workpiece in accordance with various examples of the present disclosure.

FIG. 5 is a cross-sectional view of a portion of a workpiece illustrating a deposition film protecting a plurality of features on the workpiece in accordance with various examples of the present disclosure.

FIGS. 6A-6D are cross-sectional views of a portion of a workpiece illustrating progressive stages of a deposition of a deposition species on a plurality of features sealing a plurality of gaps in accordance with various examples of the present disclosure.

FIG. 7 is a flowchart illustrating a method for processing a workpiece according to another example of the present disclosure.

### DESCRIPTION OF THE INVENTION

The present disclosure provides various methods, systems, and apparatuses for directional deposition of a deposition species of ions, neutrals, atoms, or molecules that are advantageous for use in various semiconductor fabrication processes. In particular, the directional deposition of the deposition provided in the present disclosure can serve various purposes, such as to provide, form, or otherwise fabricate a capping layer to define an air gap for electrical isolation between features of devices such as applicable to CMOS and similar integrated circuits. The directional deposition of the deposition species can further provide, form, or otherwise fabricate a capping layer for dimensional augmentation of a mask used in subsequent semiconductor processing.

The present disclosure further contemplates various systems, apparatuses, and methods for forming the deposition films described herein, and is applicable to ion implanters, etch tools, chemical vapor deposition tools, physical vapor deposition tools, and/or any other tool that transmits ions, atoms, or molecules through the gaseous phase.

Accordingly, the present disclosure will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present disclosure. It will be evident to one skilled in the art, however, that the present disclosure may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

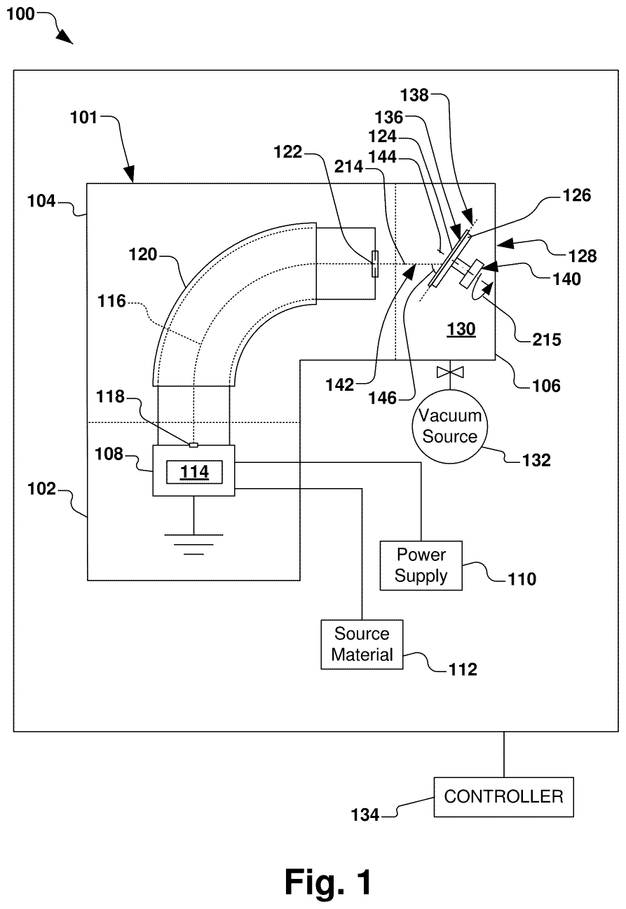

Referring now to the Figures, in accordance with one example aspect of the present disclosure, FIG. 1 illustrates a deposition system 100. The deposition system 100 in the present example comprises an ion deposition apparatus 101, however various other types of vacuum systems are also contemplated, such as plasma processing systems, or other semiconductor processing systems. The ion deposition apparatus 101 in the present example comprises a terminal 102, a beamline assembly 104, and an end station 106.

Generally speaking, an ion source 108 in the terminal 102 is coupled to a power supply 110, whereby a source material 112 comprising a deposition species is supplied to an arc chamber 114 and is ionized into a plurality of ions to form and extract an ion beam 116 through an extraction aperture 118. The ion beam 116 in the present example is directed through a mass resolving apparatus 120 (also called a source magnet), and out an aperture 122 towards the end station 106. In the end station 106, the ion beam 116 bombards a workpiece 124 (e.g., a semiconductor such as a silicon wafer, a display panel, etc.), which is selectively clamped or mounted to a workpiece support 126 (e.g., an electrostatic chuck or ESC, a mechanical clamp, a vacuum clamp, etc.).

The ion beam 116 of the present disclosure can take any form, such as a pencil or spot beam, a ribbon beam, a scanned beam, or any other form in which ions are directed toward the end station 106, and all such forms are contemplated as falling within the scope of the disclosure. Further, it is noted that in some examples, the ion beam 116 can comprise either of ions or neutrals of the source material 112. Accordingly, the present disclosure contemplates the deposition system 100 comprising any apparatus configured to transmit ions, neutrals, atoms, or molecules through the gas phase, such an ion implantation apparatus, a plasma apparatus, an etch apparatus, a chemical vapor deposition (CVD) apparatus, a physical vapor deposition (PVD) apparatus, or any other tool that can be configured to form and transmit the ion beam 116 toward the workpiece 124 positioned in the end station 106 for deposition thereon.

According to one exemplary aspect, the end station 106 comprises a process chamber 128 (e.g., a vacuum chamber), wherein a process environment 130 is associated with the process chamber. The process environment 130 generally exists within the process chamber 128, and in one example, comprises a vacuum produced by a vacuum source 132 (e.g., a vacuum pump) coupled to the process chamber and configured to substantially evacuate the process chamber. Further, a controller 134 is provided for overall control of the deposition system 100 and components, thereof.

The workpiece support 126, for example, comprises a support surface 136 configured to selectively support the workpiece 124 thereon, wherein the support surface generally defines a support plane 138. The workpiece support 126, for example, is operably coupled to a positioning apparatus 140, wherein the positioning apparatus is configured to selectively position the workpiece 124 with respect to the ion beam 116 within the process chamber 128 to receive the deposition species for deposition thereon. The positioning apparatus 140, for example, is configured to selectively rotate and/or translate the workpiece support 126 with respect to a path 142 that is generally defined by the ion beam 116.

The positioning apparatus 140, for example, is configured to selectively rotate the workpiece support 126 about a twist axis 144. In the present example, the twist axis 144 is orthogonal to the support plane 138, and hence, orthogonal to the workpiece 124. In accordance with one example, the positioning apparatus 140 is further configured to selectively position the workpiece support 126 with respect to the path 142, whereby the positioning apparatus is configured to selectively position the support plane 138 of the workpiece support 126 at a predetermined tilt angle 146 with respect to the path. As such, the positioning apparatus 140 is configured to selectively rotate and position the workpiece support 126 and the workpiece 124 with respect to the path 142 of the ion beam 116. The positioning apparatus 140, for example, can be further configured to translate the workpiece support 126 along one or more scan axes (e.g., the x-axis and/or y-axis) for scanning of the workpiece 124 through the ion beam 116. The positioning apparatus 140, for example, can comprise a robotic apparatus configured to selectively position and rotate the workpiece support 126 with respect to one or more axes (e.g., x,y,z axes).

The present disclosure contemplates the predetermined tilt angle 146, for example, is not orthogonal to the support plane 138, and is preferably substantially large (e.g., between approximately 45° to 75°) with respect to the path 142, whereby various benefits can be achieved by the present disclosure. Such a directionality of the ion beam 116 with respect to the workpiece 124 is particularly advantageous when a high molecular weight (HMW) molecule is employed as the source material 112.

Directional deposition of ions can have sufficient energy to sputter etch the workpiece 124 while deposition concurrently occurring, whereby directional films are being both deposited and sputtered at the same time, thus resulting in a relatively low deposition rate. For example, a sputter yield λ for a Si+ ion at 1 keV energy impacting a Si device feature at a 45° angle of incidence is approximately 0.75 atoms per incidental Si+ ion, leading to a deposition rate is approximately one quarter of the dose rate. Further, transmitting a high current, stable Si+ ion beam at an extraction energy below 1 keV can also be problematic.

The present disclosure overcomes such difficulties in some examples by providing a high molecular weight molecular ion, such as one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄. For example, a B₁₈H₂₂+ ion extracted at 1 kV can result in a transmitted beam with approximately 0.050 eV per boron atom, and [(CH₃)₂SiO]₅ extracted at 0.250 kV can result in a transmitted beam with approximately 0.019 keV, or 19 eV, per silicon atom, both leading to a sputter yield of approximately zero, whereby the deposition rate is approximately equal to the dose rate. By further incorporating directional film deposition of the present disclosure, the deposition system 100 can achieve directional deposition of molecular ions in an efficient manner to achieve various advantages not previously seen.

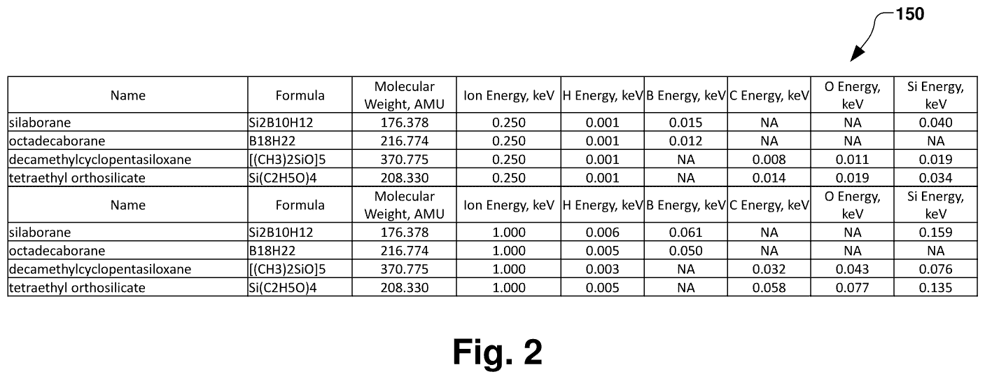

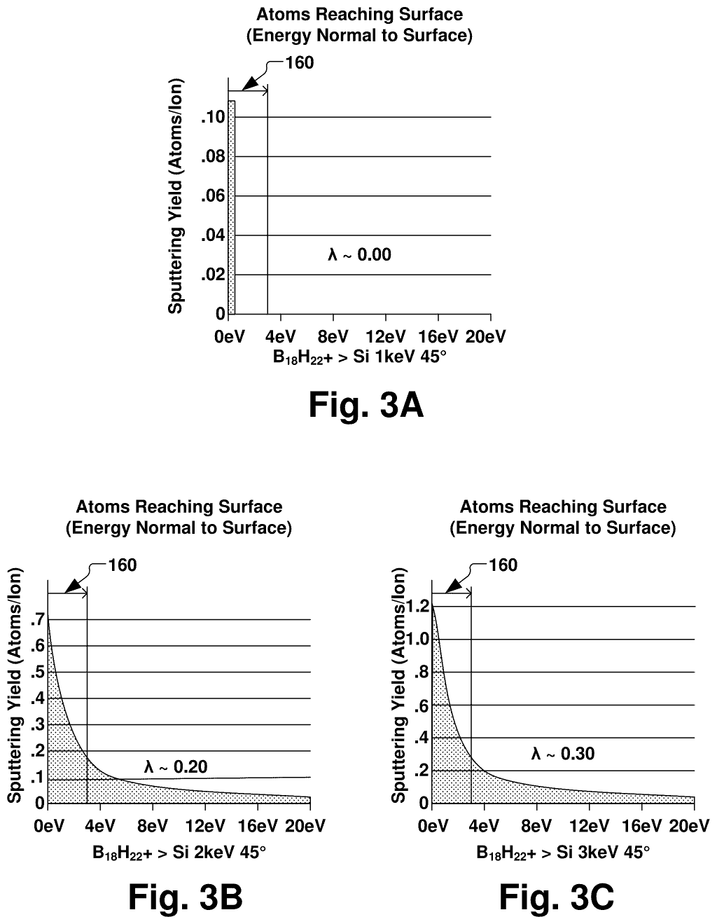

For example, vaporization, ionization and extraction of several high molecular weight molecules has been previously described for ion implantation in order to affect semiconductor electrical properties, such high molecular weight molecules have not been used for deposition described herein. The present disclosure appreciates that when molecules are ionized and extracted with unity charge, the energy per atom is equal to the quotient of the mass of the atom divided by the mass of the parent molecular ion multiplied by the final energy of the ion, as provided by example in table 150 of FIG. 2. Energies below about 25 eV/atom, or 0.025 keV/atom, will have zero atom sputter yield (λ) resulting in deposition flux approximately equal to dose rate which may be used to form a capping layer for air gap isolation or addition mask height for mask augmentation. FIGS. 3A-3C illustrate a simulation of the sputter yield λ for B₁₈H₂₂+ ions transmitted to Si at a 45° angle of incidence at 1 keV, 2 kEv, and 3 keV extraction energy, whereby non-sputtered region 160 is present below approximately 3.1 eV.

In one example, the present disclosure thus contemplates deposition being advantageously achieved by transmitting the ion beam 116 of FIG. 1 toward the workpiece 124, wherein the ion beam is formed from the source material 112 having a high molecular weight such as silaborane or octadecaborane that is condensable (e.g., a sticking coefficient>0.75) at the tilt angle 146, and wherein the tilt angle is substantially large, such as being between approximately 45° to 75°. As such, the high molecular weight of the resulting deposition atoms have a lower energy per atom. For example, octadecaborane at 1 keV results in 1.0 keV per 18 B atoms and 22 H atoms, which equates to 49.9 eV per B atom and 4.7 eV per H atom with a sputter yield of approximately zero.

Such a combination of a high molecular weight source material and tilt angle 146 being large, for example, generally defines or controls the directionality of the deposition in order to maintain the deposition in a desired region, such as a top region of a trench, gap, or via. By such a directional deposition provided by the present disclosure, various issues can be overcome during the fabrication of integrated devices (i.e., semiconductor devices) on the workpiece 124, as will now be discussed.

For example, in a first embodiment, the deposition system 100 of FIG. 1 can be advantageously employed to augment a mask used in various nano-electronic semiconductor device fabrication processes. For example, a degradation and/or reduction of a patterning mask layer (e.g., a device mask, a photoresist, or a hard mask) previously formed on the workpiece 124 can occur during etching, ion implantation, or other semiconductor processing, thus resulting in a so-called deficient mask. The deficient mask, for example, can have a remaining mask layer that is too thin to proceed to the next fabrication step (e.g., an insufficient “mask budget”), or the remaining mask layer can be too thin to complete the current processing step without suffering process-induced damage on underlying metal or dielectric layers.

The present disclosure, for example, can overcome various difficulties associated with a deficient mask by growing or augmenting the deficient mask, thus increasing the mask budget to yield a thickness that is appropriate or acceptable for current and subsequent semiconductor processing. For example, subsequent semiconductor processing, such as ion implantation, etching, deposition, etc., can demand the photoresist or hard mask have minimum thickness in order to achieve an acceptable result on the workpiece, whereby the present disclosure can advantageously augment the mask to allow for successful processing.

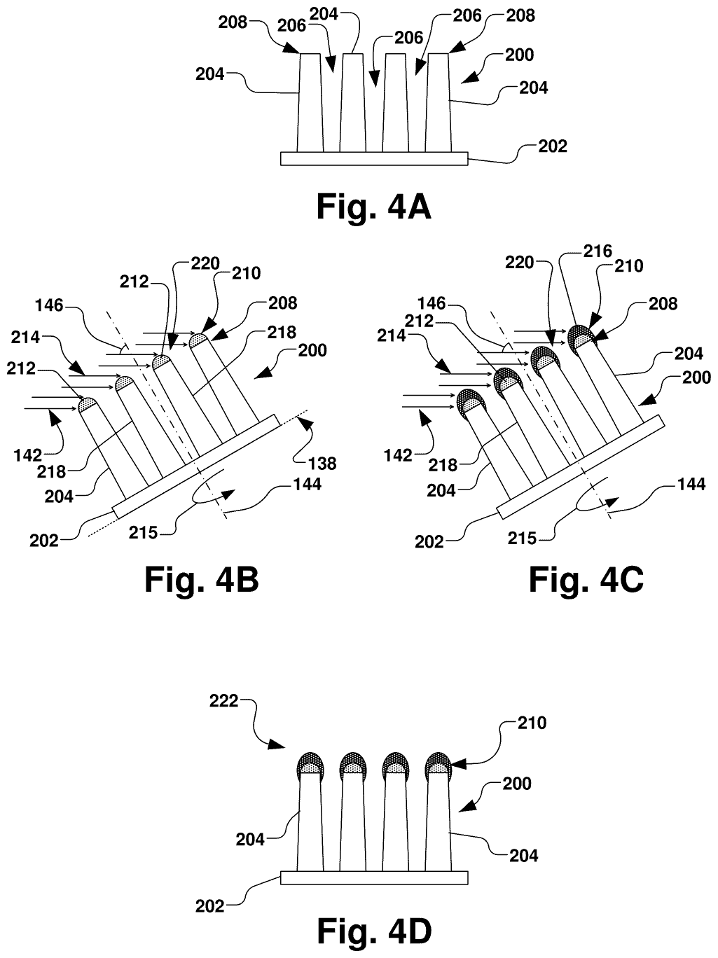

Thus, the deposition system 100 of the present disclosure can be utilized for augmenting various features on the workpiece 124, such a mask 200 (e.g., a deficient mask) previously formed over a layer 202 of the workpiece, as illustrated in FIGS. 4A-4D. Such an augmentation of the mask 200, for example, can beneficially increase the mask budget described above.

As illustrated in FIG. 4A, the mask 200, for example, can comprise a photoresist, a hard mask, or any of various masks used in semiconductor processing, whereby the mask is generally defined by one or more features 204 (e.g., one or more mask structures). The one or more features 204, for example, generally define at least one gap 206. The at least one gap 206, for example, can be an isolation gap, a via, a trench, or any gap defined within or between the one or more features 204 of the mask 200.

The deposition system 100 of FIG. 1, for example, is configured to deposit the deposition species on a predetermined portion of the one or more features 204 of FIG. 4A, such as a top portion 208 of the one or more features, thereby progressively growing a deposition film 210 shown in FIGS. 4B-4D comprised of the deposition species on the predetermined portion of the one or more features in a predetermined manner. For example, as illustrated in FIG. 4B, a first portion 212 of the deposition film 210 is deposited by a deposition beam 214 (e.g., the ion beam 116 of FIG. 1), whereby the tilt angle 146 generally limits deposition of the deposition species to the top portion 208 of the one or more features 204 generally due to shadowing caused by the interplay between the tilt angle and the one or more features with respect to the path 142 of the ion beam. Tilting of the workpiece 124 by the positioning apparatus 140 with respect to the deposition beam 214 as illustrated in FIG. 1 can be controlled by the controller 134 to provide a shadowing effect 220 shown in FIGS. 4B-4C, whereby the shadowing effect that can substantially prevent the deposition species from being deposited on the sidewall 218 of one or more features 204 of the mask 200.

Furthermore, the positioning apparatus 140 of FIG. 1 can be controlled by the controller 134 to provide a rotation 215 (e.g., a twist) of the workpiece 124 about the twist axis 144, such as illustrated in FIGS. 4B-4C, thereby providing a symmetric and uniform exposure of the top portion 208 of the one or more features 204 to the ion beam 116 with respect to the path 142. As illustrated in FIG. 4B-4C, the shadowing effect 220 increases as the deposition film 210 grows, and whereby the rotation 215 of the workpiece provides substantially symmetric coverage or deposition of the deposition species on the one or more features 204.

FIG. 4C, for example, illustrates the progression of the deposition of the deposition species to the top portion 208 of the one or more features 204, whereby a second portion 216 of the deposition film 210 is illustrated as being grown on the first portion 212. The second portion 216 deposited on the top portion 208 of the one or more features 204 further grows and causes shadowing due to the interplay between the tilt angle 146, the rotation 215 about the twist axis 144 and the one or more features with respect to the path 142 of the deposition beam 214, whereby the sidewalls 218 of the one or more features are further generally prevented from being exposed to the deposition species. Again, depending on the structure of the one or more features 204, the positioning apparatus 140 of FIG. 1 may rotate the workpiece 124 about the twist axis 144, thereby providing a symmetric and uniform exposure of the top portion 208 of the one or more features 204 of FIG. 4C to the ion beam 116 with respect to the path 142.

Due, at least in part, to the above-described low sputter yield associated with the deposition of the deposition species at the tilt angle 146, the deposition film 210 can be grown to any desired thickness, while minimizing any deleterious growth or deposition of the deposition species on the sidewalls 218 of the one or more features 204. As such, the top portion 208 of the one or more features 204 of the mask 200 may be advantageously augmented, while leaving the remainder of the mask (e.g., the sidewalls 218) generally untouched.

In one example, the mask 200 can be determined to be a deficient mask when a thickness of a photoresist or hard mask (not shown) has been degraded below a desired minimum thickness for subsequent semiconductor processing. The determination of the mask 200 as being a deficient mask can be based on theoretical, historical, or empirical evidence of the thickness or other dimensional property associated with the mask. If the mask 200 is determined to be a deficient mask, a further determination can be made regarding whether a pattern modification is desired or necessary for the subsequent processing.

In some examples, while not shown, an additional lithography process may be desired in order to modify a pattern of the mask 200 based on various desired characteristics to be achieved by the subsequent processing in the fabrication of the semiconductor device. The deposition system 100 of FIG. 1 of the present disclosure, for example, can also be configured augment such a mask to enable subsequent processing of the workpiece. For example, if the mask 200 of FIG. 4A is determined to be a deficient mask, and pattern modification is not necessary for subsequent processing, the mask (e.g., either a photoresist or hard mask) can be supplemented, augmented, or grown in accordance with the present disclosure by directing the deposition beam 214 (e.g., a capping beam) comprised of the deposition species toward the mask at a predetermined angle with respect to the workpiece (e.g., a high wafer tilt) to form the deposition film 210 (e.g., a capping film) on the mask, thereby increasing the mask budget.

For example, the deposition species and deposition beam 214 can yield a deposition film comprising nanocomposite coating (e.g., a diamond-like carbon or DLC coating) that is formed or deposited on the mask 200 (e.g., the deficient mask). For example, the source material 112 of FIG. 1 can comprise methane (CH₄), whereby the deposition beam 214 of FIGS. 4B-4C forms the deposition film 210 of FIG. 4D comprising the DLC coating. In another example, the deposition species of the source material 112 can comprise an element or molecule to form the deposition film 210 comprising an elemental or molecular coating on the deficient mask, such as a deposition beam formed from silane (SiH₄) to deposit or otherwise form a deposition film comprising silicon, or a deposition beam formed from methane (CH₄) to deposit or otherwise form a deposition film comprising carbon.

It is noted that methane and silicon are described as non-limiting examples of deposition species, and that various other elemental and molecular species are contemplated to form various deposition species comprised of atoms, molecules, ions, neutral species, and radicals. For example, the present disclosure contemplates the deposition species and deposition beam 214 comprising, but not limited to, one of C, CH₃, toluene (C₇H₈), Si, SiH₃, metals (e.g., Ta, W, Pt, Ni, etc.), or mixed deposition beams such as SiH₃ (31 amu) and O₂ (32 amu). For example, the aperture 122 associated with the mass resolving apparatus 120 of FIG. 1 can be opened up to transmit SiH₃⁺ (31 amu) and O₂⁺ (32 amu) to form a deposition film as:

SiH₃⁺O₂->SiO₂+3/2H₂ (1).

The present disclosure further appreciates that as the deposition film 210 (e.g., the capping film) of FIG. 4D grows, the deposition film will widen, whereby the at least one gap 206 (e.g., one or more vias) having a sidewall angle of the sidewall 218 with respect to the layer 202 of less than 90° can be advantageously compensated for.

The present disclosure, for example, contemplates the mass resolving apparatus 120 of the deposition system 100 of FIG. 1 being configured to selectively transmit various deposition species to form the deposition film 210 of FIGS. 4A-4D, whereby a myriad of deposition species are contemplated as falling within the scope of the present disclosure. In one example, source material 112 can comprise the deposition species of SiH₄ and NH₃, wherein the deposition film comprises SiN. In another example, the deposition species comprises SiH₄ and CH₄ and the deposition film comprises SiC. In yet another example, the deposition species comprises Al(CH₃)₃ and O₂, wherein the deposition film comprises Al₂O₃. Again, various chemistries are contemplated for the deposition species to form various deposition films, as will be appreciated by one of skill in the art.

FIG. 4D illustrates a completion of the deposition process, whereby the deposition film 210 has been advantageously grown on the one or more features 204 of the mask 200 to define an augmented mask 222. As such, the mask budget for subsequent processing of the augmented mask 222 is greater than the mask budget for the mask 200 shown in FIG. 4A, whereby the subsequent processing can comprise various semiconductor processes, such as etching, ion implantation, lithography, for further depositions.

The deposition system 100 of FIG. 1, for example, may be practiced using an ion implantation system, such as those manufactured by Axcelis Technologies, Inc. of Beverly, Massachusetts. For example, co-owned U.S. Pat. No. 7,361,914, the contents of which is incorporated by reference in its entirety, describes various features of an ion implantation system that may be utilized by the present disclosure for providing a tilt and rotation (twist) of the workpiece 124 with respect to the deposition beam 214. It is noted that various other beam formation systems are also contemplated as falling within the scope of the present disclosure.

For example, the present disclosure is further applicable to deposition processes (e.g., CVD, PVD, MOPVD) and etch processes (e.g., reactive ion etch—RIE). For example, it shall be understood that the systems and apparatuses of the present disclosure may be implemented in other semiconductor processing tools and apparatuses such as CVD, PVD, MOCVD, etching equipment, and various other semiconductor processing equipment, and all such implementations are contemplated as falling within the scope of the present disclosure, whereby the respective processing tools and apparatuses may be configured (e.g., with differentially offset apertures), to deliver ions and neutrals at the tilt angle 146 with respect to the workpiece 124 in the process chamber 128 of FIG. 1 in accordance with various aspects of the present disclosure.

Thus, the present disclosure provides a method and an apparatus for transmitting the deposition beam 214 comprising ions or a neutral species (e.g., Si⁺, SiH₃⁺, Si₃H₇⁺, C⁺, CH₃⁺, C₇H₇⁺, Si, SiH₃, [(CH₃)₂SiO]₅⁺, metal atoms, etc.) that readily condense upon striking the workpiece 124. The workpiece 124, for example, may comprise one of a silicon (Si) wafer, a silicon carbide (SiC) wafer, or a gallium nitride (GaN) wafer that may be patterned with void isolation trenches.

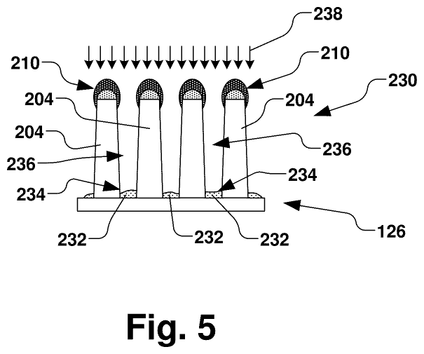

In accordance with another aspect, the present disclosure contemplates the mask augmentation processes and systems discussed above being implemented after an etching process is performed on the workpiece 124 for removal of etch residue associated therewith. Such a post-etch residue removal may be performed as a pretreatment for a subsequent deposition processing. For example, after preforming the deposition of the deposition film 210 of FIGS. 4A-4D, for example, an augmented mask 230 is illustrated in FIG. 5, whereby a residue 232 (e.g., ruthenium Ru residue) may be present at a bottom region 234 of one or more trenches 236 defined between the one or more features 204. The residue 232, for example, may be present after a subtractive (e.g., semi-damascene) etch process has been previously performed on the workpiece 124. The augmented mask 230, for example, may be a photoresist or hard mask, whereby the deposition film 210 discussed above can be utilized to enhance or protect the one or more features 204 as a pretreatment for a subsequent processing 238 (e.g., an ion etch or neutral ion beam processing) of the workpiece 124. For example, the subsequent processing 238 can comprise a chain sequence of O₂+ (e.g., to oxidize Ru and enhance reactivity), followed by (˜2 keV) argon (Ar) ion sputter, or a dry chemical etch (<2 keV) using implanted CF₄ or CO. Various examples of the subsequent processing 238 can comprise one or more of the following:

Ru+O₂+->RuO₂₍ₛ₎ (2),

RuO₂₍ₛ₎+2CF_{3(g)}+->RuF_{6(g)}+2CO_{(g)} (3), or

RuO₂₍ₛ₎+5CO_{(g)}->Ru(CO)_{5(g)}+O_{2(g)} (4).

Accordingly, the augmented mask 230 formed by the directional deposition described above can be further utilized to remove a residue metal (e.g., Ru) used in semi-damascene processing while protecting the one or more features 204.

In accordance with a second embodiment of the present disclosure, it is appreciated that low-k dielectrics (e.g., solid dielectrics), such as those used for electrical isolation in CMOS and similar integrated circuits, can have several disadvantages in semiconductor device fabrication. For example, while low-k dielectrics offer lower capacitance as compared to traditional silicon dioxide (SiO₂), the low-k dielectrics still have higher capacitance than air gaps. Low-k dielectric materials may also have reliability issues such as moisture absorption or susceptibility to mechanical stress, either of which can affect device performance and longevity. Air, on the other hand, has a very low dielectric constant, approaching a dielectric constant of one. As such, air has a minimal capacitance compared to a solid dielectric. An air gap between metal lines, for example, can significantly reduce parasitic capacitance, leading to faster signal propagation and reduced power consumption for the device. Air gap isolation further aids in reducing crosstalk between adjacent metal lines, thus improving the overall performance of the integrated circuit.

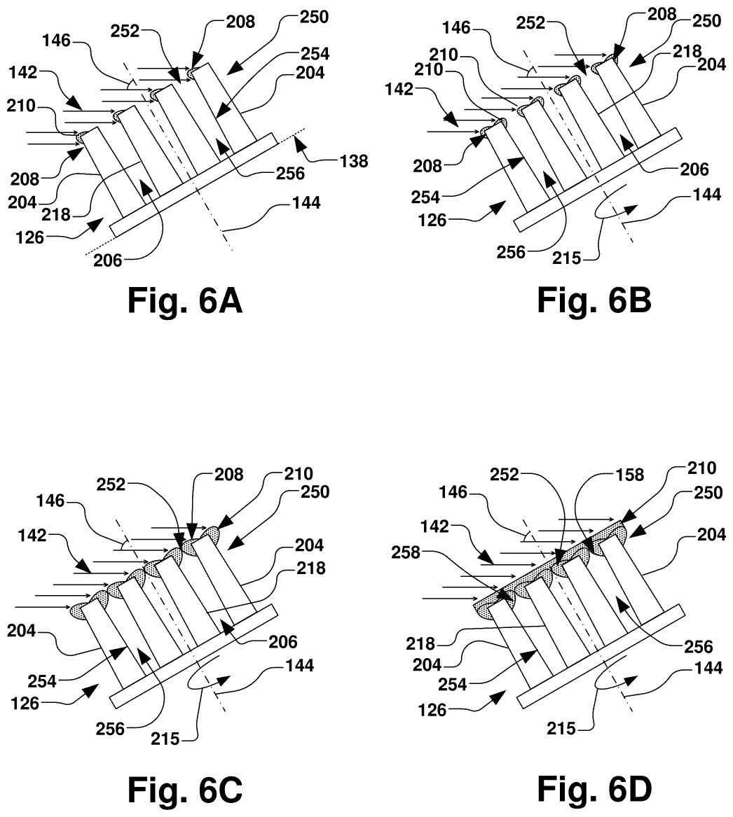

As such, the deposition system 100 of FIG. 1 can further be utilized for providing an air gap in a semiconductor device via relatively simple steps in a semiconductor manufacturing process, as compared to the traditional deposition and etching of low-k solid dielectric materials. The present disclosure contemplates the formation of an air gap or a vacuum gap by directing a deposition beam 214 (e.g., ions, neutrals, or radicals of a deposition species) at the workpiece 124, whereby the workpiece has a predetermined topography 250, as illustrated in FIGS. 6A-6D. For example, the workpiece 124 has been patterned to define the at least one gap 206 between the one or more features 204 on the workpiece. The at least one gap 206, for example, can comprise one or more vias or trenches (e.g., one or more isolation trenches) defined in the surface of the workpiece 124. The workpiece 124, for example, may comprise a silicon (Si) wafer, a silicon carbide (SiC) wafer, a gallium nitride (GaN) wafer, or other semiconductor wafer that has been patterned to define the predetermined topography 250. In one example, the deposition beam 214 is comprised of atoms or molecules from the source material 112 of FIG. 1, such as the high molecular weight deposition molecules silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄, or materials discussed above that are configured to readily condense or otherwise deposit on the workpiece 124.

In the present example shown in FIGS. 6A-6D, the deposition beam 214 is directed toward the workpiece 124, whereby the workpiece is provided at a predetermined tilt angle 146 (e.g., 45° to 75°) with respect to the deposition beam, as illustrated in FIG. 1. As such, a deposition species from the deposition beam 214 is deposited at the top portion 208 of the one or more features 204 associated with the at least one gap 206. Alternatively speaking, the deposition of the deposition species from the deposition beam 214 is yielded at a top region 252 of the at least one gap 206. Further, the predetermined tilt angle 146, for example, in conjunction with the predetermined topography 250 of the workpiece 124 (e.g., dimensions of the at least one gap 206 and the one or more features 204), substantially prevents a deposition of the deposition species at respective lower portions 254 of the one or more sidewalls 218 of the one or more features 204.

For example, the one or more features 204 may comprise a plurality of vertical features defining the at least one gap 206, wherein the at least one gap comprises at least one isolation trench 256 between the features 204. As such, in a manner similar to that discussed above, the present disclosure provides a progressive deposition of the deposition species as a deposition film 210 at the respective top region 252 of each of the at least one isolation trench 256, whereby the positioning apparatus 140 of FIG. 1 can be controlled by the controller 134 to provide the rotation 215 (e.g., a twist) of the workpiece 124 about the twist axis 144, such as illustrated in FIGS. 6B-6D, thereby providing a symmetric and uniform exposure of the top portion 208 of the one or more features 204 to the deposition beam 214 with respect to the path 142. As such, the at least one gap 206 (e.g., the at least one isolation trench 256) can be sealed at the respective top region 252 thereof associated with the top portion 208 of the one or more features 204. Accordingly, the deposition film 210 thus progressively grown until the top region 252 the at least one gap 206 is sealed, as illustrated in FIG. 6C. As illustrated in FIG. 6D, the deposition beam 214 may continue to deposit the deposition film until the deposition film entirely seals the at least one gap 206 to define at least one gap isolation structure 158, whereby a gas (e.g., air) or a vacuum is sealed within the at least one gap 206 by the at least one gap isolation structure. It is noted that the gap isolation structure is contemplated to define an air gap, a vacuum gap, or any non-solid-form gap between or within the one or more features 204 or structures on the workpiece of FIG. 1.

The present disclosure contemplates various deposition apparatuses for forming the above-described deposition beam, as well as various configurations of apparatuses configured to form and/or transmit a beam or a cloud of ions, neutrals, or radicals of a deposition species that are configured to readily condense upon striking the workpiece. For example, the present disclosure contemplates various deposition apparatuses (e.g., the deposition system 100 of FIG. 1) that are configured to form and transmit a beam or cloud of ions, neutrals, or radicals of a deposition species such as one or more of Si⁺, SiH₃⁺, Si₃H₇⁺, [(CH₃)₂SiO]₅+, C⁺, CH₃⁺, C₇H₇⁺, Si, SiH₃, and any metal atoms (e.g., W, Ta, Ru, etc.) that is configured to readily condense upon striking the workpiece 124 (e.g., a wafer comprised of Si, SiC, GaN, GaAs, or any other semiconductor), whereby the various deposition apparatuses of the present disclosure can be utilized to fabricate sealed cavities or air gap isolation structures. Apparatuses for the above-described depositions of deposition species are contemplated by the present disclosure to include, but not be limited to, ion implanters, etch tools, chemical vapor deposition tools, physical vapor deposition tools, or any other tool or apparatus configured transmits ions, atoms, or molecules through the gas phase.

The present disclosure, for example, contemplates the deposition apparatus comprising a mass resolution apparatus configured to selectively transmit various deposition species to form the deposition film, and all such deposition species are believed to fall within the scope of the present disclosure. In one example, the deposition species comprises SiH₄ and NH₃, wherein the deposition film comprises SiN. In another example, the deposition species comprises SiH₄ and CH₄ and the deposition film comprises SiC. In yet another example, the deposition species comprises Al(CH₃)₃ and O₂, wherein the deposition film comprises Al₂O₃. Again, various chemistries are contemplated for the deposition species to form various deposition films, as will be appreciated by one of skill in the art.

Thus, the present disclosure provides various systems, apparatuses, and methods for the formation of air or vacuum gaps in semiconductor devices by an angled deposition of ions or neutral materials or radicals. Accordingly, the present disclosure advantageously contemplates various systems, apparatuses, and methods for manufacturing of low-k (air or vacuum) dielectric transistors by sealing off open trenches using the above-described angled deposition technique.

Further, it is to be appreciated that the present disclosure is applicable to ion implanters, etch tools, chemical vapor deposition tools, physical vapor deposition tools, and/or any other tool or apparatus configured to that transmits ions, atoms, or molecules through the gaseous phase.

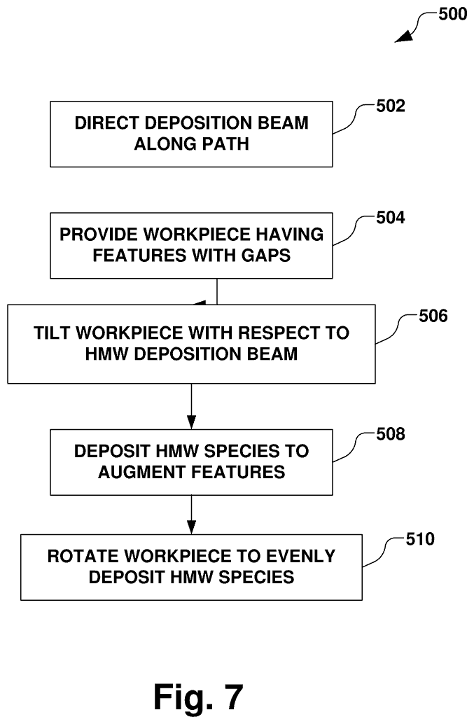

In accordance with another example, FIG. 7 illustrates a method 500 for processing a semiconductor workpiece, whereby the deposition system 100 of FIG. 1 may be employed. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

The method 500 of FIG. 7 begins at act 502 by directing a deposition beam along a path, wherein the deposition beam comprises a deposition species. The deposition beam, for example, can comprise an ion beam and a neutral beam comprised of a high molecular weight deposition species. For example, the deposition beam can comprise an ion beam comprising a high molecular weight deposition species selected from one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄.

In act 504, a workpiece is provided along the path, wherein the workpiece has a one or more features defined thereon. The one or more features define one or more gaps extending between a lower portion and a top portion of the one or more features, respectively.

The workpiece is tilted at a predetermined tilt angle with respect to the path of the deposition beam in act 506. In act 508, the deposition species is then deposited on the top portion of the one or more features, thereby defining a deposition film on the top portion of the one or more features. The deposition film deposited in act 508, for example, increases one or more dimensions of the top portion of the one or more features, wherein the predetermined tilt angle, the one or more features, and the deposition film generally prevent the deposition film from depositing on the lower portion of the one or more features. In one example, the deposition film is generally prevented from depositing on the lower portion of the one or more features due to a shadowing effect. Further, in act 510, the workpiece is rotated with respect to the deposition beam, wherein the deposition film is uniformly deposited on the top portion of the one or more features.

In some examples, the deposition of the deposition species on the top portion of the one or more features in act 508 seals one of a gas or a vacuum within the one or more gaps. In other examples, the one or more features are associated with a mask, wherein the deposition of the deposition species on the top portion of the one or more features in act 508 augments the mask for subsequent processing of the workpiece.

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. The term “exemplary” as used herein is intended to imply an example, as opposed to best or superior. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A deposition system comprising:
an ion deposition apparatus configured to direct a deposition species along a path;
a workpiece support configured to selectively support a workpiece along a support plane, wherein the workpiece comprises one or more features defining at least one gap; and
a positioning apparatus configured to selectively position the workpiece support with respect to the path to receive the deposition species, wherein the positioning apparatus is configured to selectively position the support plane of the workpiece support at a predetermined tilt angle with respect to the path, and wherein the workpiece support is further configured to selectively rotate the workpiece with respect to the path, wherein the predetermined tilt angle is not orthogonal to the support plane, wherein the ion deposition apparatus is configured to deposit the deposition species on a predetermined portion of the one or more features, thereby growing a deposition film comprised of the deposition species on the predetermined portion of the one or more features in a predetermined manner.

2. The deposition system of claim 1, wherein the deposition film substantially seals the at least one gap to respectively define at least one gap isolation structure.

3. The deposition system of claim 1, wherein the workpiece support is configured to selectively vary the predetermined tilt angle with respect to the path between approximately 45° to 75°.

4. The deposition system of claim 1, wherein the ion deposition apparatus comprises an ion implantation system configured to define an ion beam, wherein the ion beam comprises the deposition species.

5. The deposition system of claim 1, wherein the deposition species comprises one of Si⁺, SiH₃⁺, Si₂H₅⁺, Si₃H₇⁺, C⁺, CH₃⁺, C₇H₇⁺, Si, SiH₃, or metal atoms.

6. The deposition system of claim 1, wherein the deposition species comprises one or more condensable species, wherein the ion deposition apparatus is configured to transmit the condensable species toward the workpiece in a gaseous phase, and wherein the condensable species is configured to condense on the workpiece.

7. The deposition system of claim 1, wherein the deposition species comprises one or more of Ta, W, Ru, Pt, and Ni.

8. The deposition system of claim 1, wherein the ion deposition apparatus is configured to deposit the deposition species at a top portion of the one or more features.

9. The deposition system of claim 1, wherein the one or more features comprise a plurality of vertical features defined on a surface of the workpiece, and wherein the at least one gap comprises at least one trench defined between at least two of the plurality of vertical features wherein the ion deposition apparatus is configured to deposit the deposition species proximate to a respective top opening of each of the at least one trench.

10. The deposition system of claim 1, wherein the ion deposition apparatus comprises an ion implantation system configured to direct a beam of ions or neutrals of the deposition species toward the workpiece, wherein the beam of ions or neutral species are configured to condense upon striking the workpiece.

11. The deposition system of claim 1, wherein the ion deposition apparatus comprises one of a CVD apparatus, a PVD apparatus, and an etch apparatus, and a directional reactive ion etch apparatus.

12. The deposition system of claim 1, wherein the one or more features comprise a mask, whereby the deposition film is configured to increase one or more dimensions of the mask.

13. The deposition system of claim 12, wherein the mask comprises one or more of a deficient mask, a device mask, a photoresist, and a hard mask.

14. The deposition system of claim 13, wherein the mask comprises a pattern having a plurality of void isolation trenches.

15. The deposition system of claim 1, wherein the deposition species comprises SiH₄ and the deposition film comprises Si.

16. The deposition system of claim 1, wherein the deposition species comprises CH₄ and the deposition film comprises a diamond-like carbon (DLC) coating.

17. The deposition system of claim 1, wherein the ion deposition apparatus comprises a mass resolution apparatus configured to selectively transmit the deposition species toward the workpiece to form the deposition film.

18. The deposition system of claim 1, wherein the deposition species comprises SiH₃⁺ (31 amu) and O₂⁺ (32 amu).

19. The deposition system of claim 1, wherein the deposition species comprises SiH₄ and NH₃ and wherein the deposition film comprises SiN.

20. The deposition system of claim 1, wherein the deposition species comprises SiH₄ and CH₄ and wherein the deposition film comprises SiC.

21. The deposition system of claim 1, wherein the deposition species comprises Al(CH₃)₃+O₂ and wherein the deposition film comprises Al₂O₃.

22. The deposition system of claim 1, wherein the deposition species comprises a high molecular weight molecule.

23. The deposition system of claim 22, wherein the high molecular weight molecule comprises one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄.

24. A method for semiconductor processing, the method comprising:
directing a deposition beam along a path, wherein the deposition beam comprises a deposition species;
providing a workpiece along the path, wherein the workpiece has one or more features defined thereon, and wherein the one or more features define one or more gaps extending between a lower portion and a top portion of the one or more features, respectively;
tilting the workpiece at a predetermined tilt angle with respect to the deposition beam; and
depositing the deposition species on the top portion of the one or more features, thereby defining a deposition film on the top portion of the one or more features and increasing one or more dimensions of the top portion of the one or more features, wherein the predetermined tilt angle, the one or more features, and the deposition film generally prevent the deposition film from depositing on the lower portion of the one or more features.

25. The method of claim 24, wherein the deposition beam comprises a high molecular weight deposition species.

26. The method of claim 25, wherein the deposition beam comprises one of an ion beam and a neutral beam.

27. The method of claim 24, wherein the deposition film is generally prevented from depositing on the lower portion of the one or more features due to a shadowing effect.

28. The method of claim 24, further comprising rotating the workpiece with respect to the deposition beam, wherein the deposition film is uniformly deposited on the top portion of the one or more features.

29. The method of claim 24, wherein depositing the deposition species on the top portion of the one or more features seals one of a gas or a vacuum within the one or more gaps.

30. The method of claim 24, wherein the deposition species comprises one of silaborane (Si₂B₁₀H₁₂), octadecaborane (B₁₈H₂₂), decamethylcyclopentasiloxane [(CH₃)₂SiO]₅, or tetraethyl orthosilicate Si(C₂H₅O)₄.
